(19) United States
(12) Patent Application Publication
(10) Pub. No.: US 2026/0254277 A1
(43) Pub. Date: Aug. 27, 2026

(54) WIRELESS POWER TRANSMISSION SYSTEM AND METHOD FOR STABLE OPERATION UNDER ENVIRONMENTAL VARIATIONS AT A FIXED FREQUENCY

(71) Applicant: UNIVERSITY-INDUSTRY COOPERATION GROUP OF KYUNG HEE UNIVERSITY, Yongin-si (KR)

(72) Inventors: Sanghoek KIM, Suwon-si (KR); Tae Won Seo, Yongin-si (KR)

(73) Assignee: UNIVERSITY-INDUSTRY COOPERATION GROUP OF KYUNG HEE UNIVERSITY, Yongin-si (KR)

(21) Appl. No.: 19/432,285

(22) Filed: Dec. 24, 2025

(30) Foreign Application Priority Data
Feb. 25, 2025 (KR) 10-2025-0024574

(51) Int. Cl. H02J 50/12; H03L 7/085; H03L 7/099

(52) U.S. Cl. CPC H02J 50/12; H03L 7/085; H03L 7/099

(57) ABSTRACT

The present invention relates to a wireless power transmission technology that operates stably at a fixed frequency without communication between a transmitter (Tx) and a receiver (Rx), and more particularly, to a technology in which a phase-locked loop (PLL) is applied to the transmitter to fix the operating frequency, and the tunable capacitor in the receiver is adjusted in correspondence with a change in the tunable capacitor of the transmitter, thereby maintaining identical resonant frequencies between the transmitter and the receiver in real time to ensure consistent transmission efficiency even under environmental variations. The wireless power transmission system of the present disclosure can be applied to various electronic devices such as wearable devices, flexible displays, medical implants, electric vehicles, and electric mobility, and enables more stable wireless power transmission by solving problems of the related art.

### CROSS-REFERENCE TO RELATED APPLICATION

This application claims priority from and the benefit of Korean Patent Application No. 10- 2025-0024574 filed on February 25, 2025, in the Korean Intellectual Property Office, the disclosure of which is incorporated herein by reference.

### BACKGROUND OF THE DISCLOSURE

### Field of the Disclosure

Example embodiments relate to a wireless power transmission technology that operates stably at a fixed frequency without communication between a transmitter and a receiver, and more particularly, to a technology in which a phase-locked loop (PLL) is applied to the transmitter to fix an operating frequency, and a variable capacitor in the receiver is adjusted in correspondence with a variable capacitor in the transmitter that changes accordingly, such that the resonant frequencies of the transmitter and the receiver are adjusted in real time to remain identical, thereby ensuring a constant power transmission efficiency even under environmental variations.

### Description of the Related Art

The wireless power transfer (WPT) technology has been recently commercialized in various applications such as mobile devices, wearable devices, electric vehicle charging, and medical implants, and continuous research has been conducted to realize such systems in commercial products.

Early wireless power transmission technologies were based on magnetic induction and magnetic resonance methods, and had a limitation in that power could be transmitted efficiently only when the transmitter and the receiver were fixed in position. In recent studies, technologies have been proposed that utilize communication between a transmitter and a receiver to adjust the operate frequency, thereby compensating for positional variations and maintaining high efficiency, and commercialization efforts are underway for such resilient systems. However, these methods inherently requires bidirectional communication to tune the operating frequency, which is a significant drawback.

If such communication is implemented in an active communication scheme using a separate communication channel, an additional frequency band is required and power consumption increases due to the active communication, whereas if it is implemented in a passive communication scheme that uses the same channel as the power transfer channel, as in RFID, communication errors are likely to occur when the relative position between the transmitter and the receiver changes, thereby preventing the seamless power transfer.

To solve these problems, the concept of parity-time symmetry (PT-symmetry) has recently been introduced. In such technologies, when the position or orientation of the transmitter and the receiver changes, the optimal frequency can be automatically adjusted without additional communication between the transmitter and the receiver, thereby maintaining power transmission efficiency. Although PT-symmetry–based technologies guarantee optimal transmission efficiency, the operating frequency still varies as the distance between the transmitter and the receiver changes. When the variation in operating frequency is large, it may cause electromagnetic interference with other wireless devices, so in commercial environments it is desirable to use a fixed frequency. Moreover, PT-symmetry–based technologies operate effectively only when the resonators of the transmitter and the receiver have the same coil structure, which limits their applicability to devices of various sizes and reduces their commercial scalability.

This research was supported by the NAVER Digital Bio Innovation Research fund, funded by the NAVER Corporation (Grant No. 3720230040). The funder had no role in the design, data collection and analysis, and reporting of the study.

### National R&D Program Supporting This Invention

### Project Unique ID 1711193314

### Project Number 2021-0-02046-003

### Ministry Ministry of Science and ICT

### Project Management (Specialized) Agency Institute of Information & Communications Technology Planning & Evaluation (IITP)

### R&D Program Title (Innovation Act) ICT·Broadcasting Innovation Talent Training_2023

### Research Project Title [Government] 2023 ITRC 6H Next-Generation Mobile Communication Technology Development (Phase 2, Year 1) (3/8)

### Performing Organization Kyung Hee University, Industry-Academic Cooperation Foundation

### Research Period July 1, 2021 – December 31, 2028

### National R&D Program Supporting This Invention

### Project Unique ID 1711192384

### Project Number 2023R1A2C2004236

### Ministry Ministry of Science and ICT

### Project Management (Specialized) Agency National Research Foundation of Korea (NRF)

### R&D Program Title (Type 1-2) Mid-career Research Program

### Research Project Title [Mid-career Research Type 1-2] Parity-Time Symmetry-based Stable Wireless Power and Data Simultaneous Transmission System and Multielectrode Epicardial Implant Device Utilizing the Same (1/5)

### Performing Organization Kyung Hee University (International Campus)

### Research Period March 1, 2023 – February 29, 2028

### National R&D Program Supporting This Invention

### Project Unique ID 2710007393

### Project Number 00393808

### Ministry Ministry of Science and ICT

### Project Management (Specialized) Agency Institute of Information & Communications Technology Planning & Evaluation (IITP)

### R&D Program Title (Innovation Act) Broadcasting and Communications Industry Technology Development (Radio/Wireless/Satellite)_2024

### Research Project Title Development of AI-based RF Component and System Design Technology for Future Ultra-High Productivity, Phase 1 (1/5)

### Performing Organization Sogang University, Industry-Academic Cooperation Foundation

### Research Period April 1, 2024 – December 31, 2028

### Patent Document 1 U.S. Patent Application Publication No. US 2024/0204568 A1, titled "HIGH-ORDER PARITY-TIME SYMMETRY WIRELESS POWER TRANSFER SYSTEM AND METHOD"

### Patent Document 2 U.S. Patent Application Publication No. US 2024/0162757 A1, titled "MULTI-LOAD WIRELESS POWER TRANSFER SYSTEM BASED ON HIGH-ORDER ANTI-PT SYMMETRY"

### Patent Document 3 Japanese Patent Application Publication No. JP 2022-121324 A, titled "MAGNETIC RESONANCE-TYPE WIRELESS POWER SUPPLY DEVICE"

### SUMMARY

The present disclosure aims to address the problem of transmission efficiency reduction caused by variations in system’s resonant frequency when the physical position or form of a power receiver of a device changes.

The present disclosure aims to address the problem of increased system complexity in conventional wireless power transmission technologies that require additional communication between a transmitter and a receiver.

The present disclosure aims to address the problem of electromagnetic interference resulting from the wide frequency bandwidth required by PT-symmetry–based wireless power transfer technologies.

The present disclosure aims to overcome the limitation of conventional systems that can operate only when the resonators of the transmitter and receiver have identical structures, thereby enabling application to devices of various sizes.

The present disclosure aims to address a frequency interference problem caused by an unfixed operating frequency in existing wireless power transmission systems and to ensure stable operation even with a fixed transmission frequency in commercial environments.

According to one embodiment, a wireless power transmission system may include a transmitter configured to receive input power from an external power source and to set a transmission-side resonant frequency, a receiver configured to receive power from the transmitter in a resonantly coupled state and to set a reception-side resonant frequency, a phase-locked loop (PLL) included in the transmitter and configured to maintain the transmission-side resonant frequency at a fixed frequency, a variable capacitor included in the receiver and configured to adjust capacitance to maintain the same resonant frequency as the transmission-side resonant frequency.

According to one embodiment, the transmitter may include a transmission resonator adjusted by the phase-locked loop (PLL) to maintain the transmission-side resonant frequency at the fixed frequency, a phase detector configured to output a control signal for adjusting the frequency of the transmission resonator, and a voltage-controlled oscillator (VCO) configured to adjust the transmission-side resonant frequency based on an output of the phase detector.

According to one embodiment, the transmitter may further include a frequency detector configured to generate a frequency locking signal for maintaining the transmission-side resonant frequency, and a frequency controller configured to adjust the frequency of the transmission resonator based on an output of the frequency detector.

According to one embodiment, the receiver may include a variable capacitor configured to adjust capacitance to maintain the same resonant frequency as the transmitter, and a capacitance adjuster configured to adjust the capacitance of the variable capacitor.

According to one embodiment, the capacitance adjuster may include a voltage detector configured to measure an output voltage of the receiver, and a capacitance controller configured to adjust the variable capacitance according to an output of the voltage detector so as to maintain the same resonant frequency as the transmitter.

According to one embodiment, the transmitter may include a transmitter-side internal tuning circuit configured to adjust capacitance inside the transmitter to fix the transmission-side resonant frequency.

According to one embodiment, the transmitter-side internal tuning circuit may include a digital electronic variable capacitor configured to adjust capacitance to maintain a constant operating frequency of the wireless power transmission system.

According to one embodiment, a wireless power transmission method may include receiving input power from an external power source and setting a transmission-side resonant frequency, adjusting the transmission-side resonant frequency using a phase-locked loop (PLL) to maintain the frequency at a fixed value, receiving power from the transmitter in a resonantly coupled state and setting a reception-side resonant frequency, and adjusting a variable capacitance in the receiver so as to maintain the same resonant frequency as the transmission-side resonant frequency.

According to one embodiment, the operating frequency may be fixed by applying a phase-locked loop (PLL) to the transmitter, and the resonant frequency of the receiver may be varied by adjusting a variable capacitor of the receiver, thereby maintaining constant transmission efficiency even under environmental variations.

According to one embodiment, since additional communication between the transmitter and the receiver is not required, the system structure may be simplified and overall stability may be improved.

According to one embodiment, the system may operate within a narrow frequency bandwidth, thereby eliminating the need for a wide frequency range required in conventional technologies and preventing electromagnetic interference.

According to one embodiment, by adjusting the variable capacitor of the receiver, receivers of various sizes may maintain the same resonant frequency, allowing the system to be applied without size limitations of the transmitter or receiver.

According to one embodiment, high transmission efficiency may be maintained even under physical deformation or positional movement, making the system applicable to next-generation electronic devices such as wearable devices and flexible displays.

### BRIEF DESCRIPTION OF THE FIGURES

Embodiments will be described in more detail with regard to the figures, wherein like reference numerals refer to like parts throughout the various figures unless otherwise specified, and wherein:

FIG. 1 is a diagram illustrating a wireless power transmission system according to one embodiment.

FIG. 2 is a diagram showing a performance comparison among various non-radiative wireless power transmission methods under dynamic scenarios.

FIG. 3 is a diagram illustrating circuit configurations and power transmission efficiency at different stages of development under dynamic environments.

FIG. 4 is a diagram showing a comparison with conventional technologies.

FIG. 5 is a diagram illustrating a wireless power transmission method according to one embodiment.

### DETAILED DESCRIPTION OF THE DISCLOSURE

Specific structural or functional descriptions of embodiments according to the concept of the present disclosure, as set forth in this specification, are merely illustrative for the purpose of explaining the embodiments, and the embodiments according to the concept of the present disclosure may be implemented in various forms and are not limited to the embodiments described herein.

The embodiments according to the concept of the present disclosure may be modified in various ways and may have a variety of configurations. Accordingly, certain embodiments are illustrated in the drawings and described in detail in this specification. However, this is not intended to limit the embodiments to specific disclosed forms, but is to include modifications, equivalents, and alternatives that fall within the spirit and scope of the present disclosure.

Terms such as “first” and “second” may be used to describe various components, but such components should not be limited by these terms. These terms are used merely to distinguish one component from another. For example, a first component may be referred to as a second component without departing from the scope of the present disclosure, and similarly, the second component may also be referred to as the first component.

When an element is referred to as being “connected to” or “coupled to” another element, it may be directly connected or coupled to the other element, or intervening elements may be present. In contrast, when an element is referred to as being “directly connected to” or “directly coupled to” another element, it is understood that no intervening element is present. Expressions describing relationships between components, such as “between,” “directly between,” or “adjacent to,” are to be interpreted in a similar manner.

The terminology used herein is for the purpose of describing particular embodiments only and is not intended to be limiting of the present disclosure. The singular forms include the plural forms unless the context clearly dictates otherwise. In this specification, terms such as “comprise,” “include,” or “have” specify the presence of stated features, integers, steps, operations, components, or combinations thereof, but do not preclude the presence or addition of one or more other features, integers, steps, operations, components, or combinations thereof.

Unless otherwise defined, all technical and scientific terms used herein have the same meaning as commonly understood by one of ordinary skill in the art to which this disclosure pertains. Terms defined in generally used dictionaries are to be interpreted in a manner consistent with their meaning in the context of the relevant technical field, and unless explicitly defined herein, they are not to be interpreted in an idealized or overly formal sense.

Hereinafter, embodiments will be described in detail with reference to the accompanying drawings. However, the scope of the patent application is not limited or restricted by such embodiments. The same reference numerals denote the same elements throughout the drawings.

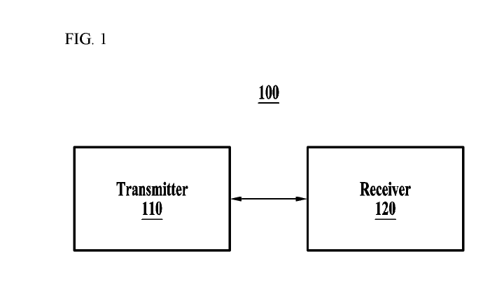

FIG. 1 is a diagram illustrating a wireless power transmission system 100 according to one embodiment.

The wireless power transmission system 100 according to one embodiment includes a transmitter 110 and a receiver 120.

The transmitter 110 according to one embodiment is configured to receive input power from an external power source and to set a transmission-side resonant frequency. The transmitter 110 also includes a phase-locked loop (PLL) configured to maintain the transmission-side resonant frequency constant.

The phase-locked loop (PLL) is included within the transmitter 110 and is configured to adjust and maintain the transmission-side resonant frequency at a fixed frequency. The PLL may include a transmission resonator, a phase detector, and a voltage-controlled oscillator (VCO).

The transmission resonator is a component adjusted by the PLL to maintain the transmission-side resonant frequency at the fixed frequency. The phase detector is a component configured to output a control signal for adjusting the frequency of the transmission resonator. The voltage-controlled oscillator (VCO) performs an operation of adjusting the transmission-side resonant frequency based on an output of the phase detector.

The transmitter 110 may further include a transmitter-side internal tuning circuit. The transmitter-side internal tuning circuit performs a function of adjusting capacitance within the transmitter 110 to fix the transmission-side resonant frequency. The transmitter-side internal tuning circuit may include a digital electronic variable capacitor configured to adjust capacitance to maintain the transmission-side resonant frequency constant.

The digital electronic variable capacitor performs a function of adjusting capacitance within the transmitter 110 to maintain the transmission-side resonant frequency constant.

The transmitter 110 may also include a frequency detector and a frequency controller configured to maintain the transmission-side resonant frequency.

The frequency detector performs a function of generating a frequency locking signal for maintaining the transmission-side resonant frequency.

The frequency controller performs a function of adjusting the frequency of the transmission resonator based on an output of the frequency detector.

The receiver 120 is configured to receive power from the transmitter 110 in a resonantly coupled state and to set a reception-side resonant frequency.

The receiver 120 includes a variable capacitor configured to maintain the reception-side resonant frequency identical to the transmission-side resonant frequency.

The variable capacitor is included within the receiver 120 and performs a function of adjusting capacitance so as to maintain the reception-side resonant frequency identical to the transmission-side resonant frequency.

The receiver 120 may further include a capacitance adjuster configured to adjust the capacitance of the variable capacitor.

The capacitance adjuster is a component that performs a function of adjusting the capacitance of the variable capacitor. The capacitance adjuster may include a voltage detector and a capacitance controller.

The voltage detector performs a function of measuring an output voltage of the receiver 120.

The capacitance controller performs a function of adjusting the variable capacitance according to an output of the voltage detector so as to maintain the same resonant frequency as the transmitter 110.

The wireless power transmission system 100 may include a frequency synchronization controller configured to synchronize the resonant frequencies between the transmitter 110 and the receiver 120.

The frequency synchronization controller performs a function of adjusting a variable capacitance of the receiver 120 so as to maximize a receive voltage of the receiver 120 and maintaining a resonant frequency of the transmitter 110 and a resonant frequency of the receiver 120 identical to each other.

The wireless power transmission system 100 operates such that the transmitter 110 and the receiver 120 transmit wireless power while synchronizing their resonant frequencies.

The transmitter 110 receives input power from an external power source and sets a transmission-side resonant frequency.

The transmitter 110 maintains the transmission frequency at a fixed frequency by using a phase-locked loop (PLL).

The receiver 120 receives power from the transmitter 110 in a resonantly coupled state and sets a reception-side resonant frequency.

The receiver 120 adjusts variable capacitance to maintain the reception-side resonant frequency identical to the transmission-side resonant frequency of the transmitter 110.

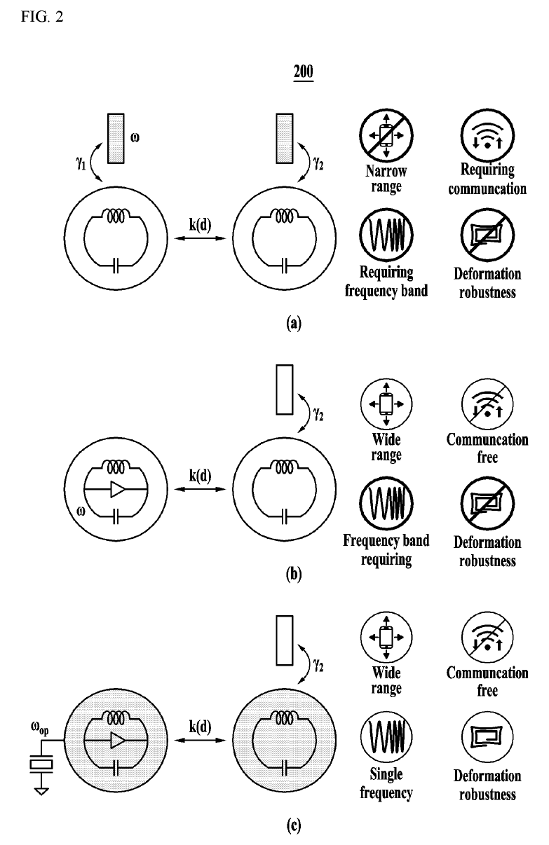

FIG. 2 is a diagram showing a performance comparison among various non-radiative wireless power transmission methods under dynamic scenarios.

FIG. 2 compares a conventional wireless power transmission method (a), a PT-symmetry-based wireless power transmission method (b), and a frequency-fixed PT-symmetry wireless power transmission method (c) according to the present disclosure, and analyzes differences among these methods in terms of frequency operating range, communication requirements, frequency bandwidth demand, and robustness against receiver deformation.

In the conventional wireless power transmission method (a), the transmitter (Tx) and the receiver (Rx) communicate with each other to adjust the transmission frequency and power intensity in real time.

The transmitter (Tx) receives data from the receiver (Rx) related to received voltage, coupling strength, and load condition in order to adjust transmission power and transmission frequency.

Based on the information from the receiver (Rx), the transmitter (Tx) adjusts the output frequency and power intensity through an oscillator and a power control unit of the transmitter.

The transmitter (Tx) and the receiver (Rx) may require a separate communication channel for mutual data exchange. Alternatively, they may use the same channel as the powering for the communication, and employ a load modulation technique to convey feedback data within the reflected signal.

However, the conventional wireless power transmission method (a) has a narrow frequency operating range and a sharply reduced power transmission efficiency when distance, position, or physical deformation between the transmitter and receiver changes.

The conventional wireless power transmission method exhibits little robustness against deformation and requires continuous adjustment of the transmission frequency according to environmental variations, which results in the need for a wide frequency bandwidth.

Therefore, the conventional wireless power transmission method tends to operate unstably under environmental changes and can guarantee optimal transmission performance only at specific positions or under fixed conditions.

The PT-symmetry-based wireless power transmission method (b) is a method in which the transmitter (Tx) and the receiver (Rx) are designed to satisfy a parity-time symmetry (PT-symmetry) condition.

In the PT-symmetry-based wireless power transmission method, the transmitter (Tx) includes a nonlinear gain element, enabling automatic adjustment of the transmission frequency. The transmitter (Tx) employs an amplification circuit utilizing feedback to automatically search for a resonant frequency that achieves optimal transmission efficiency.

The receiver (Rx) has the same resonant structure as the transmitter (Tx) and autonomously adjusts its resonant frequency based on nonlinear resonance phenomena generated from the transmitter (Tx).

The PT-symmetry-based wireless power transmission method (b) does not require direct communication between the transmitter and the receiver and has a characteristic that allows the transmitter to automatically adjust the frequency without feedback regarding the receiver’s state.

The PT-symmetry-based wireless power transmission method (b) exhibits robustness against distance variations; however, the transmitter and receiver must share the same self-resonant frequency. Because the operating frequency automatically varies according to distance changes, a wide frequency bandwidth is required.

When physical deformation occurs in the receiver (Rx), the PT-symmetry condition may be broken, resulting in a potential reduction in transmission efficiency.

The PT-symmetry-based wireless power transmission method (b) has the advantage of automatically finding an optimal frequency without communication between the transmitter and the receiver; however, structural form of the receiver should be the same as the transmitter. Deformation of either receiver or transmitter results in the performance degradation.

The present disclosure (c) provides a frequency-fixed PT-symmetry wireless power transmission method that maintains the PT-symmetry concept while fixing the operating frequency, thereby overcoming the drawbacks of conventional wireless power transmission methods and PT-symmetry-based methods.

The transmitter (Tx) includes a phase-locked loop (PLL) configured to maintain the transmission frequency at a fixed frequency.

The receiver (Rx) includes a tunable capacitor configured to automatically adjust its capacitance so as to maintain the same resonant frequency as the transmitter.

The transmitter (Tx) fixes the transmission frequency through the PLL, while the receiver (Rx) detects the received voltage in real time and adjusts the variable capacitance accordingly, thereby maintaining identical resonant frequencies between the transmitter and the receiver at all times.

Unlike conventional PT-symmetry-based methods, the present disclosure can maintain the PT-symmetry condition even when the structural coil forms of the transmitter and receiver differ.

The present disclosure exhibits robustness against physical deformation of both the transmitter and receiver, enabling stable wireless power transmission even in deformable environments.

The present disclosure does not require communication between the transmitter and receiver, and unlike conventional methods, does not require a wide frequency bandwidth.

The present disclosure complements the shortcomings of conventional methods and PT-symmetry-based approaches and maintains the PT-symmetry condition even when the operating frequency is fixed, thereby ensuring high power transmission efficiency despite receiver deformation or distance variation.

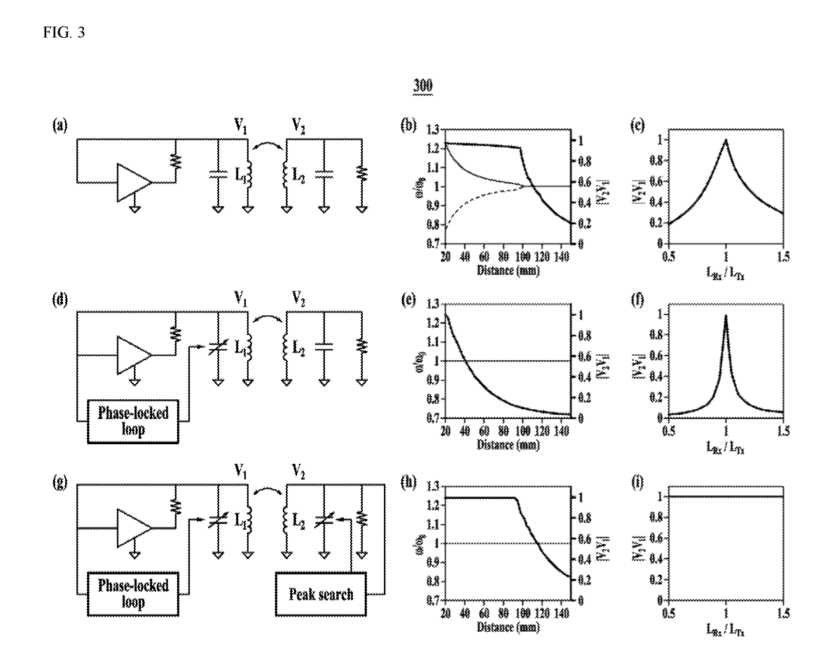

FIG. 3 is a diagram illustrating circuit configurations and power transmission efficiency at different stages of development under dynamic environments.

FIG. 3 compares (a) a PT-symmetric wireless power transmission method, (d) a frequency-locked PT-asymmetric wireless power transmission method including a phase-locked loop (PLL), and (g) a frequency-locked PT-symmetric wireless power transmission method according to the present disclosure including a peak detection function, and analyzes differences among these methods in terms of how the resonant frequency between the transmitter and the receiver is maintained, variations in power transmission efficiency, system response characteristics according to distance changes, and robustness against environmental variations.

The wireless power transmission system according to the present disclosure includes a transmission resonator, a voltage-controlled oscillator (VCO), a frequency detector, and a frequency controller configured to maintain the transmission-side resonant frequency using the PLL.

By applying a peak search function to match a resonant frequency of the transmitter and a resonant frequency of a receiver, enables stable wireless power transmission even under environmental changes.

The diagram (a) of FIG. 3 illustrates a PT-symmetric wireless power transmission method.

In the PT-symmetric wireless power transmission method, power is transmitted on automatically adjusted resonant frequency between the transmitter (Tx) and the receiver (Rx).

The transmitter (Tx) includes a feedback power amplifier and a resonant circuit and has a configuration for transmitting power at a system resonant frequency.

The receiver (Rx) includes a receiving resonant circuit and receives power from the transmitter (Tx) in a resonantly coupled state.

When the distance between the transmitter (Tx) and the receiver (Rx) changes, the resonant coupling strength varies, which causes the change in system resonant frequency.

Because the transmitter (Tx) has a feedback loop, the system oscillates at its resonant frequency, thereby maintaining transmission efficiency up to a large distance.

The PT-symmetric method (a) has low deformation robustness in the receiver (Rx) and a limitation in that it different self-resonant frequency of transceivers breaks the PT symmetry.

In the graphs (b) and (c) of FIG. 3, it is confirmed that in the PT-symmetric method (a), power transmission efficiency maintains high up to a large distance, but the oscillating frequency should change according to the distance, resulting in wide frequency allocation to avoid interference with other devices.

(d) Wireless Power Transmission Method Including a Phase-Locked Loop (PLL)

The diagram (d) of FIG. 3 illustrates a frequency-locked PT-asymmetric wireless power transmission method.

The phase-locked loop (PLL) is a circuit configured to maintain the resonant frequency of the transmitter (Tx) at a constant frequency.

The transmitter (Tx) includes a transmission resonator incorporating the PLL and performs a function of adjusting the transmitter to maintain the transmission frequency constant through the PLL.

The receiver (Rx) includes a resonant circuit identical to that of the conventional method (a); however, it has a limitation in that its resonant frequency is not automatically adjusted to match the frequency determined by the PLL of the transmitter (Tx).

Although the transmitter (Tx) can maintain a transmission frequency fixed, when a coupling strength between the transmitter (Tx) and the receiver (Rx) varies, a resonant frequency of the receiver (Rx) may fail to change accordingly, which can result in a decrease in transmission efficiency.

When a physical deformation occurs in the receiver (Rx), a resonant frequency of the transmitter (Tx) to which the PLL is applied and a resonant frequency of the receiver (Rx) may become different from each other, which may cause a decrease in power transmission efficiency.

In the graphs (e) and (f) of FIG. 3, it can be observed that the system oscillates at a constant frequency in contrast to the PT-symmetric method (a); however, power transmission efficiency is not stable and shows a gradual decreasing trend.

(g) Optimized Wireless Power Transmission Method Including Peak Search Function According to the Present Disclosure

The diagram (g) of FIG. 3 illustrates a frequency-locked PT-symmetric wireless power transmission method including a peak search function proposed by the present disclosure.

The present disclosure not only fixes the resonant frequency of the transmitter (Tx) using a phase-locked loop (PLL) but also includes a tunable capacitor configured to automatically adjust the resonant frequency of the receiver (Rx).

The transmitter (Tx) includes a transmission resonator and a voltage-controlled oscillator (VCO) incorporating the PLL, and maintains the transmission-side resonant frequency at a constant frequency.

The receiver (Rx) includes a capacitance adjuster including a variable capacitor and a peak search function, and changes a receiver variable capacitor while sensing a receiver voltage in real time, and changes the variable capacitor so that the receiver voltage is maximized according to peak search, thereby matching a resonant frequency of the receiver (Rx) to that of the transmitter (Tx).

Thus, the present disclosure is designed to maintain high power transmission efficiency even when a distance between the transmitter (Tx) and the receiver (Rx) changes or when physical deformation occurs.

In the graphs (h) and (i) of FIG. 3, it is confirmed that power transmission efficiency remains constant even as the distance increases at a constant transmission frequency, even when deformation occurs.

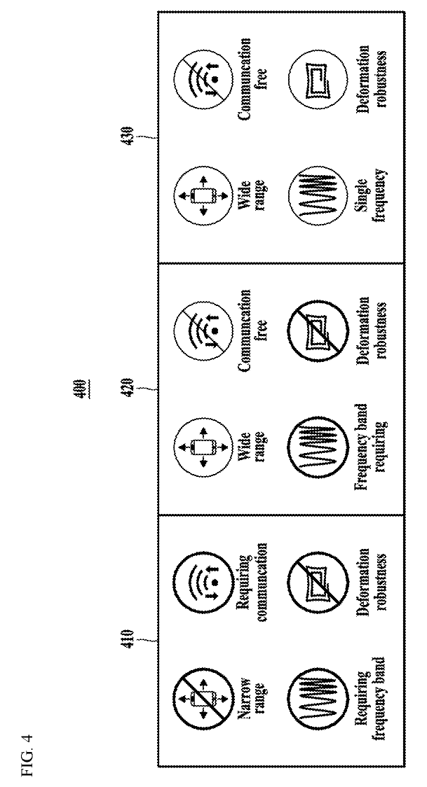

FIG. 4 is a diagram comparing the performance between a conventional wireless power transmission system and the wireless power transmission system according to the present disclosure.

FIG. 4 compares a conventional commercial wireless power transmission system 410, a PT-symmetry-based wireless power transmission system 420, and a frequency-fixed PT-symmetry wireless power transmission system 430 according to the present disclosure, and analyzes the differences among these systems in terms of frequency operating range, communication requirements between the transmitter and the receiver, frequency bandwidth demand, and robustness of the receiver against deformation.

The present disclosure includes, in a transmitter (Tx), a phase-locked loop (PLL) and a voltage-controlled oscillator (VCO) to maintain a system resonant frequency of a transmitter (Tx) and a receiver (Rx) at a predetermined operating frequency, and includes, in a receiver (Rx), a tunable capacitor and a capacitance adjuster, and is characterized in that individual resonant frequencies of the transmitter and the receiver are automatically adjusted.

FIG. 4 visually compares how these technical differences affect overall system performance.

The conventional commercial wireless power transmission system 410 requires a separate communication link between the transmitter (Tx) and the receiver (Rx) in order to perform wireless power transmission.

The transmitter (Tx) adjusts the transmission frequency based on feedback information regarding the reception state received from the receiver (Rx), and is designed to modify the transmission power and frequency in real time during this process.

Because communication between the transmitter (Tx) and the receiver (Rx) is essential, additional hardware for feedback circuits and data transmission/reception is required.

The conventional commercial wireless power transmission system 410 has a narrow operating area, and when distance variation or physical deformation occurs between the transmitter (Tx) and the receiver (Rx), continuous frequency adjustment is necessary to maintain resonance.

The conventional commercial wireless power transmission system 410 requires a wide frequency allocation, and when deformation of the receiver (Rx) or environmental variation occurs, power transmission efficiency sharply decreases.

As shown in FIG. 4, the conventional system 410 exhibits stable performance only within a narrow operating range, requires communication between the transmitter (Tx) and the receiver (Rx), demands a wide frequency bandwidth, and lacks robustness against deformation.

The PT-symmetry-based wireless power transmission system 420 is a method designed such that the transmitter (Tx) and the receiver (Rx) satisfy a parity-time symmetry (PT-symmetry) condition.

The transmitter (Tx) includes a nonlinear gain element configured to automatically adjust the resonant frequency.

The PT-symmetry-based wireless power transmission system 420 automatically adjusts the resonant frequency without requiring direct communication between the transmitter (Tx) and the receiver (Rx).

Compared with the conventional system 410, the PT-symmetry-based wireless power transmission system 420 provides a wider frequency operating range and maintains high power transmission efficiency without requiring communication between the transmitter (Tx) and the receiver (Rx).

However, since a PT-symmetry based wireless power transmission system 420 still has a system resonant frequency formed by the transmitter (Tx) and the receiver (Rx) that varies according to a change in distance, it has a drawback in that a wide frequency band is required.

In addition, when physical deformation occurs in the receiver (Rx), the PT-symmetry condition may be broken, which can lead to degradation in power transmission efficiency.

As shown in FIG. 4, the PT-symmetry-based system 420 has a wide frequency operating range and can operate without communication, but it still requires a wide frequency bandwidth and lacks robustness against deformation.

The frequency-fixed PT-symmetry wireless power transmission system 430 according to the present disclosure includes a phase-locked loop (PLL) and a voltage-controlled oscillator (VCO) within the transmitter (Tx) to fix the transmission frequency.

The receiver (Rx) includes a tunable capacitor and a capacitance adjuster configured to automatically adjust the resonant frequency of the receiver (Rx) to match the resonant frequency of the transmitter (Tx).

The system 430 of the present disclosure can always maintain a resonant frequency between the transmitter (Tx) and the receiver (Rx) identical, and is designed to maintain high power transmission efficiency even when a distance between the transmitter (Tx) and the receiver (Rx) changes or when a physical deformation of the receiver (Rx) occurs.

The system 430 of the present disclosure compensates for the drawbacks of the conventional system 410 and the PT-symmetry-based system 420, operates at a single fixed frequency, does not require communication between the transmitter (Tx) and the receiver (Rx), and exhibits excellent robustness against deformation.

As shown in FIG. 4, the system 430 of the present disclosure provides a wide operating range, can operate without communication, functions at a single frequency, and ensures robustness against deformation.

FIG. 4 compares the performance differences among the conventional system 410, the PT-symmetry-based system 420, and the proposed system 430, demonstrating that the present disclosure achieves superior performance over conventional techniques.

The present disclosure maintains the resonant frequency of the transmitter (Tx) by employing a phase-locked loop (PLL) and includes a tunable capacitor and a peak search function in the receiver (Rx) to automatically adjust the resonant frequencies of the transmitter (Tx) and the receiver (Rx), thereby maintaining constant power transmission efficiency.

The present disclosure enables stable wireless power transmission even in dynamic environments and addresses performance degradation issues caused by distance variation and deformation of the receiver (Rx) in conventional systems.

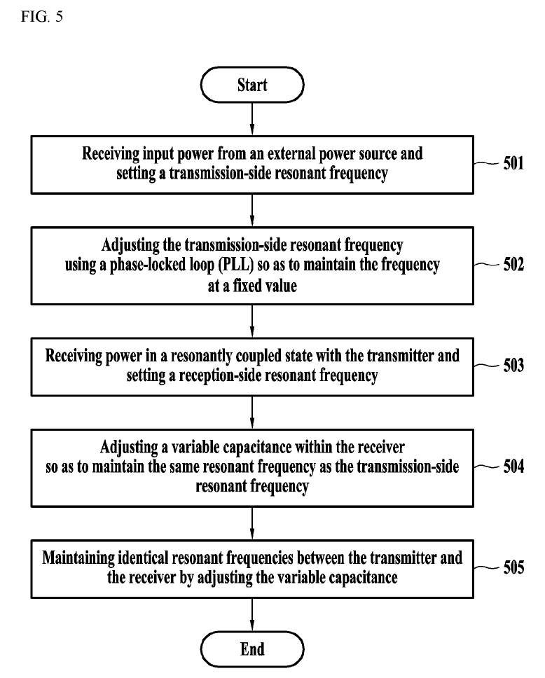

FIG. 5 is a flowchart illustrating a wireless power transmission method according to the present disclosure.

Each step shown in FIG. 5 specifically represents a procedure for performing stable wireless power transmission while maintaining the resonant frequency between the transmitter (Tx) and the receiver (Rx) constant.

The wireless power transmission method according to the present disclosure includes a function of automatically adjusting the resonant frequencies between the transmitter (Tx) and the receiver (Rx), thereby maintaining constant power transmission efficiency even in dynamic environments.

A feature of the present disclosure is that it includes a phase-locked loop (PLL: Phase-Locked Loop) that fixes a system resonant frequency, and a tunable capacitor that automatically adjusts a resonant frequency of the receiver (Rx) to be identical to a resonant frequency of the transmitter (Tx) without communication with the transmitter (Tx).

In the wireless power transmission method according to one embodiment, the system receives input power from an external power source and sets the resonant frequency of the transmitter (Tx) (step 501).

The transmitter (Tx) receives input power from a power source and drives a transmitting resonant circuit using the received power.

The transmitter (Tx) includes a power amplifier (PA) to deliver the input power to the transmitting resonant circuit, thereby amplifying and supplying the transmission power.

The transmitter (Tx) forms the resonant circuit by combining an internal inductor (L) and a capacitor (C) to set the resonant frequency of the transmitting resonator, and determines an initial system resonant frequency.

The transmitter (Tx) prepares to stabilize the transmission frequency by employing the phase-locked loop (PLL) so that the initially set system resonant frequency does not fluctuate.

After setting a resonant frequency, the transmitter (Tx) operates to maintain a transmission frequency even if a position or a shape of the receiver (Rx) or the transmitter (Tx) changes in a subsequent stage.

In the wireless power transmission method according to one embodiment, the transmission-side transmission frequency is adjusted using a phase-locked loop (PLL) to maintain the frequency at a fixed value (step 502).

The transmitter (Tx) adjusts the frequency of a transmission resonator by employing the PLL so as to keep the transmission frequency constant.

The transmitter (Tx) includes, within the PLL, a phase detector, a loop filter, and a voltage-controlled oscillator (VCO), thereby continuously detecting the phase of the transmission frequency and adjusting it to prevent any frequency deviation.

Using the PLL, the transmitter (Tx) compensates for frequency drift that may occur due to external environmental changes, temperature variations, or intrinsic circuit fluctuations, and maintains a constant transmission frequency.

Even after the PLL is calibrated, the transmitter (Tx) continuously monitors the frequency in real time and corrects any deviation so that the resonant frequency remains at the preset value.

In the wireless power transmission method according to one embodiment, power is received from the transmitter in a resonantly coupled state, and the reception-side resonant frequency is set (step 503).

The receiver (Rx) receives power in a self-resonant coupled state with the transmitter (Tx).

The receiver (Rx) activates a resonant circuit to induce power from the transmitter (Tx) and determines an initial resonant frequency based on the inductance and the capacitance of the receiver (RX).

To synchronize with the frequency of the transmitter (Tx), the receiver (Rx) detects a received voltage using an internal voltage detector and analyzes the received power level.

The receiver (Rx) analyzes variations in the received power to determine whether the currently set resonant frequency matches the frequency of the transmitter (Tx), and performs correction if necessary.

In the wireless power transmission method according to one embodiment, the tunable capacitance within the receiver (Rx) is adjusted so as to maintain a resonant frequency identical to that of the transmitter (Tx) (step 504).

The receiver (Rx) adjusts the capacitance of an internal tunable capacitor in real time to maintain a resonant frequency identical to that of the transmitter (Tx).

The receiver (Rx) includes a Capacitance Adjustment Unit to adjust a capacitance of a tunable capacitor.

The receiver (Rx) finely adjusts a value of the tunable capacitor so that a receiver voltage is maximized by matching a resonant frequency of the receiver (Rx) to a resonant frequency of the transmitter (Tx), thereby achieving maximum power transmission efficiency.

In the wireless power transmission method according to one embodiment, the transmission-side resonant frequency and the reception-side resonant frequency can be maintained identical through adjustment of the tunable capacitance (step 505).

After completion of adjustment of the variable capacitance, the receiver (Rx) maintains a frequency identical to the resonant frequency of the transmitter (Tx).

The wireless power transmission method of the present disclosure is designed to automatically synchronize a resonant frequency without communication between the transmitter (Tx) and the receiver (Rx), thereby ensuring stable power transmission even in a dynamic environment.

The wireless power transmission method of the present invention is designed to automatically synchronize the resonant frequencies between the transmitter (Tx) and the receiver (Rx) without any communication therebetween, thereby ensuring stable power transmission even under dynamic environmental conditions.

The present invention is configured such that the resonant frequency of the transmitter (Tx) is fixed using a phase-locked loop (PLL), and the tunable capacitance of the receiver (Rx) is adjusted to synchronize the resonant frequency of the receiver (Rx) with that of the transmitter (Tx).

Through this configuration, the system can maintain resonance even when physical deformation occurs between the transmitter (Tx) and the receiver (Rx), providing higher power transmission efficiency and operational stability compared with conventional systems.

By applying a PLL to the transmitter (Tx) to fix the operating frequency and adjusting the tunable capacitor of the receiver (Rx) to maintain resonance, the system ensures consistent transmission efficiency regardless of environmental variations.

Furthermore, because no additional communication between the transmitter (Tx) and the receiver (Rx) is required, the overall system structure is simplified, enhancing reliability and stability. The system can also operate within a narrow frequency bandwidth, thereby eliminating the need for a wide frequency range required by conventional technologies and preventing electromagnetic interference.

In addition, by adjusting the tunable capacitor of the receiver (Rx), the system can maintain identical resonant frequencies across receivers of various sizes, enabling applicability regardless of the physical dimensions of the transmitting and receiving units.

The apparatus described above may be implemented by hardware components, software components, or a combination of both hardware and software components.

For example, the apparatuses and components described in the embodiments may be implemented using one or more general-purpose computers or special-purpose computers, such as a processor, controller, arithmetic logic unit (ALU), digital signal processor (DSP), microcomputer, field-programmable array (FPA), programmable logic unit (PLU), or microprocessor capable of executing and responding to instructions.

The processing device may execute one or more software applications running on an operating system (OS).

In response to the execution of software, the processing device may access, store, manipulate, process, and generate data.

For convenience of explanation, a single processing device may be described; however, those skilled in the art will understand that the processing device may include multiple processing elements and/or multiple types of processing elements.

For example, the processing device may include multiple processors, or a combination of a processor and a controller. Other processing configurations, such as a parallel processor configuration, may also be used.

Software may include a computer program, code, instructions, or any combination thereof, which configure the processing device to operate in a desired manner or instruct the processing device, individually or collectively, to perform specific functions.

The software and/or data may be embodied permanently or temporarily in any type of machine, component, physical or virtual device, computer storage medium, or transmission signal wave, so as to be interpreted or executed by the processing device or to provide instructions or data thereto.

The software may also be distributed across a networked computer system, stored, or executed in a distributed manner.

The software and data may be stored on one or more computer-readable recording media.

The method according to the embodiments may be implemented as program instructions executable by various computer means and recorded on a computer-readable medium.

The computer-readable medium may include program instructions, data files, data structures, or a combination thereof.

The program instructions recorded on the medium may be specially designed and configured for the embodiments, or may be generally available and known to those skilled in computer software.

Examples of the computer-readable recording medium include magnetic media such as hard disks, floppy disks, and magnetic tapes; optical media such as CD-ROMs and DVDs; magneto-optical media such as floptical disks; and hardware devices specially configured to store and execute program instructions, such as ROM, RAM, and flash memory.

Examples of program instructions include machine code generated by a compiler, as well as high-level language code executable by a computer using an interpreter or the like.

The above-described hardware components may operate as one or more software modules to perform the operations of the embodiments, and vice versa.

Although the embodiments have been described with reference to limited drawings, those skilled in the art will appreciate that various modifications and alterations can be made from the above description.

For example, the described technologies may be performed in a different order, or the described systems, structures, apparatuses, and circuits may be combined, substituted, or replaced in different forms with other components or equivalents to achieve substantially the same results.

Accordingly, other implementations, other embodiments, and equivalents thereof are considered to fall within the scope of the following claims.

What is claimed is:

1. A wireless power transmission system comprising:
a transmitter configured to receive input power from an external power source and to set a transmission-side resonant frequency;
a receiver configured to receive power from the transmitter in a resonantly coupled state and to set a reception-side resonant frequency;
a phase-locked loop (PLL) included in the transmitter and configured to maintain the transmission-side resonant frequency at a fixed frequency;
a variable capacitor included in the receiver and configured to adjust capacitance so as to maintain the same resonant frequency as the transmission-side resonant frequency; and
a frequency synchronization controller configured to adjust the capacitance of the variable capacitor such that the transmission-side resonant frequency and the reception-side resonant frequency remain identical.

2. The wireless power transmission system of claim 1,
wherein the transmitter comprises:
a transmission resonator adjusted by the phase-locked loop (PLL) to maintain the transmission-side resonant frequency at the fixed frequency;
a phase detector configured to output a control signal for adjusting the frequency of the transmission resonator; and
a voltage-controlled oscillator (VCO) configured to adjust the transmission-side resonant frequency based on an output of the phase detector.

3. The wireless power transmission system of claim 2,
wherein the transmitter further comprises:
a frequency detector configured to generate a frequency locking signal for maintaining the system resonant frequency; and
a frequency controller configured to adjust the frequency of the transmission resonator based on an output of the frequency detector.

4. The wireless power transmission system of claim 1,
wherein the receiver comprises:
a variable capacitor configured to adjust capacitance to maintain the same resonant frequency as the transmitter; and
a capacitance adjuster configured to adjust the capacitance of the variable capacitor.

5. The wireless power transmission system of claim 4,
wherein the capacitance adjuster comprises:
a voltage detector configured to measure an output voltage of the receiver; and
a capacitance controller configured to adjust the variable capacitance according to an output of the voltage detector so as to maintain the same resonant frequency as the transmitter.

6. The wireless power transmission system of claim 1,
wherein the transmitter comprises a transmitter-side internal tuning circuit configured to adjust capacitance inside the transmitter to fix the transmission-side resonant frequency.

7. The wireless power transmission system of claim 6,
wherein the transmitter-side internal tuning circuit comprises a digital or analog electronic or mechanical variable capacitor configured to adjust capacitance so as to maintain a transmission-side resonant frequency constant.

8. A wireless power transmission method comprising:
receiving input power from an external power source and setting a transmission-side resonant frequency;
adjusting the transmission-side resonant frequency using a phase-locked loop (PLL) to maintain the frequency at a fixed value;
receiving power from the transmitter in a resonantly coupled state and setting a reception-side resonant frequency; and
adjusting a variable capacitance in the receiver so as to maintain the same resonant frequency as the transmission-side resonant frequency.

9. The wireless power transmission method of claim 8,
wherein the step of maintaining the transmission-side resonant frequency at the fixed frequency comprises:
using a phase detector to output a control signal for adjusting the frequency of a transmission resonator; and
using a voltage-controlled oscillator (VCO) to adjust the transmission-side resonant frequency based on an output of the phase detector.

10. The wireless power transmission method of claim 8,
wherein the step of maintaining identical resonant frequencies between the transmitter and the receiver comprises:
adjusting a capacitance within the receiver so that, even when a position of the transmitter and the receiver changes, a resonant frequency of the transmitter and a resonant frequency of the receiver vary identically to provide a system resonant frequency at a fixed frequency.
